(19) United States
(12) Patent Application Publication
(10) Pub. No.: US 2026/0190701 A1
(43) Pub. Date: Jul. 2, 2026

(54) DISPLAY APPARATUS

(71) Applicant: LG Display Co., Ltd., Seoul (KR)

(72) Inventors: Miso Kim, Seoul (KR); Byungjin Kim, Paju-si (KR); Hanseok Lee, Paju-si (KR); Donggu Kim, Paju-si (KR)

(21) Appl. No.: 19/354,737

(22) Filed: Oct. 9, 2025

(30) Foreign Application Priority Data
Dec. 30, 2024 (KR) 10-2024-0200897

(51) Int. Cl. H10K 59/131; H10K 71/00; H10K 102/00

(52) U.S. Cl. CPC H10K 59/131; H10K 71/861; H10K 2102/341

(57) ABSTRACT

A display apparatus includes a plurality of data lines disposed between a plurality of neighboring sub-pixels, a scan line disposed below the plurality of sub-pixels, repair circuits disposed at locations where the plurality of data lines intersect the scan line. The repair circuit is configured such that a first repair line may be connected by bypassing two defective or disconnected points of the scan line and a second repair line may be connected by bypassing two defective or disconnected points of the data line.

### CROSS REFERENCE TO RELATED APPLICATION

Pursuant to 35 U.S.C. § 119(a), this application claims the benefit of an earlier filing date and right of priority to Korean Patent Application No. 10-2024-0200897, filed on December 30, 2024 in the Korean Intellectual Property Office, the contents of which are incorporated by reference herein in their entirety.

### TECHNICAL FIELD

The present disclosure relates to a display apparatus.

### BACKGROUND

Organic light-emitting diode (OLED) display apparatuses display images using light-emitting elements that emit light by themselves. Each light-emitting element is disposed in an active area AA of a display panel, receives data voltage through a data line, and receives gate voltage through a scan line. Each of the data line and the scan line is formed of a metal material. Accordingly, when electrostatic discharge occurs in the active area, there is a problem that a short occurs in the data line or the scan line, thereby causing electrostatic damage (ESD).

### SUMMARY

In a display apparatus according to one implementation of the present disclosure, a plurality of data lines may be disposed between a plurality of neighboring sub-pixels, a scan line may be disposed below the plurality of sub-pixels, repair circuits may be disposed at points where the plurality of data lines intersect the scan line, the repair circuit may be configured such that a first repair line may be connected by bypassing two defective or disconnected points of the scan line and a second repair line may be connected by bypassing two defective or disconnected points of the data line.

In a display apparatus according to another implementation of the present disclosure, a repair circuit may be disposed at each of points of a display panel in which a plurality of data lines disposed between a plurality of neighboring sub-pixels intersect a scan line disposed below the plurality of sub-pixels, a first repair line of the repair circuit may connect the defective or disconnected scan line by bypassing two defective or disconnected points, a second repair line of the repair circuit may connect the defective or disconnected data line by bypassing two defective or disconnected points, a scan signal may be applied to a plurality of sub-pixels through a scan driver, a data signal may be applied to the plurality of sub-pixels through a data driver, and the scan driver and the data driver may be controlled by a timing controller.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate implementations of the disclosure and together with the description serve to explain the principle of the disclosure.

FIG. 1 is a plan view showing a pixel configuration of a display apparatus according to an implementation of the present disclosure.

FIG. 2 is a plan view showing a pixel configuration in which a repair circuit is disposed according to the implementation of the present disclosure.

FIG. 3 is a view showing an example of a configuration of the repair circuit according to the implementation of the present disclosure.

FIG. 4 is a view showing an example of a configuration of a repair circuit according to another implementation of the present disclosure.

FIG. 5 is a view showing an example of a cross-sectional structure of the repair circuit according to the implementation of the present disclosure.

FIG. 6 is a view showing an example of a cross-sectional structure of the repair circuit according to another implementation of the present disclosure.

FIG. 7 is a view showing an example of a cross-sectional structure of a repair circuit according to still another implementation of the present disclosure.

FIG. 8 is a view showing an example in which an auxiliary power line is used as a repair line for the repair circuit according to still another implementation of the present disclosure.

FIG. 9 is a view showing an example in which a main power line is used as a repair line for the repair circuit according to still another implementation of the present disclosure.

FIG. 10 is a view showing an example in which a gate line and data lines that are opened due to an electrostatic discharge defect are repaired through the auxiliary power line according to the implementation of the present disclosure.

FIG. 11 is a view showing an example in which a gate line and a data line that are shorted due to an electrostatic discharge defect are repaired through the auxiliary power line according to the implementation of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTIONS

The present disclosure provides a display apparatus that can allow a data line or a scan line that is shorted due to electrostatic discharge to be repaired.

Implementations of the present disclosure can provide a display apparatus that can allow a disconnected data line or scan line to be repaired through a repair line disposed around a data line or a scan line even when electrostatic discharge occurs in an active area.

According to the implementations of the present disclosure, even when electrostatic discharge occurs in the active area, it is possible to repair the disconnected data line or the scan line by bypassing the disconnected point through the repair line disposed around the data line or the scan line.

According to the implementations of the present disclosure, it is possible to selectively repair only the defective pixels by bypassing the disconnected point.

According to the implementations of the present disclosure, it is possible to reduce or prevent damage or defects of the display panel due to electrostatic discharge that can occur during the manufacturing process.

According to the implementations of the present disclosure, although defects in the product can affect the operation of the display panel to further increase power consumption, it is possible to reduce or prevent such defects in the product, thereby reducing the power consumption of the product.

According to the implementations of the present disclosure, it is possible to reduce the power consumption of the product, thereby reducing or preventing a decrease in the lifetime of the display apparatus.

According to the implementations of the present disclosure, it is possible to provide a long-life and low-power display apparatus by reducing the power consumption of the product and preventing a decrease in the lifetime of the product.

According to the implementations of the present disclosure, it is possible to reduce the power consumption of the product, thereby reducing or minimizing a degradation in the lifetime of the display panel and achieving the quality improvement of the display apparatus.

In addition, according to the implementations of the present disclosure, it is possible to eliminate the defects of the display panel, thereby improving the quality of the product and securing the reliability of the product.

The effects of the present disclosure are not limited to the above-described effects, and other effects that are not described will be able to be clearly understood by those skilled in the art based on the following description.

Specific effects of the present disclosure together with the above-described effects are described together with a description of the following detailed matters for carrying out the implementations of the disclosure.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Further aspects and advantages are discussed below in conjunction with implementations of the disclosure.

Reference will now be made in detail to implementations of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure and methods for achieving them will become clear by referencing implementations described below in detail in conjunction with the accompanying drawings. However, the present disclosure is not limited to the implementations disclosed below but will be implemented in various different forms, these implementations are merely provided to make the disclosure of the present disclosure complete and fully inform those skilled in the art to which the present disclosure pertains of the scope of the present disclosure.

Since shapes, sizes, ratios, angles, numbers, etc. disclosed in the drawings for describing the implementations of the present disclosure are illustrative, the present disclosure is not limited to the shown items. The same reference number denotes the same components throughout the disclosure. In addition, in describing the present disclosure, when it is determined that the detailed description of a related known technology may unnecessarily obscure the gist of the present disclosure, the detailed description thereof will be omitted. When “comprise,” “have,” “consist of,” ” or the like described herein are used, other parts may be added unless “only” is used. When a component is expressed in a singular form, it includes a case in which the component is provided as a plurality of components unless specifically stated otherwise.

Any implementation described herein as an “example” is not necessarily to be construed as preferred or advantageous over other implementations.

In construing a component, the component is construed as including a margin of error even when there is no separate explicit description related to the margin of error.

When a positional relationship is described, for example, when the positional relationship between two parts is described using “on,” “above,” “under,” “next to,” or the like, one or more other parts may be located between the two parts, for example, unless “immediately,” “directly,” or “close to” is used.

When a temporal relationship is described, when the temporal relationship is described using the term “after,” “subsequently,” “then,” “before,” or the like, it may also include a non-consecutive case unless the term “immediately” or “directly” is used.

Although a first, a second, and the like are used to describe various components, these components are not limited by these terms. These terms are only used to distinguish one component from another component. Therefore, a first component described below may be a second component within the technical idea of the present disclosure.

In the description of the components of the present disclosure, terms such as first, second, A, B, (a), and (b) may be used. These terms are only for the purpose of distinguishing one component from another component, and the nature, sequence, order, or the like of the corresponding component is not limited by these terms.

When a certain component is described as being “connected,” “coupled,” “joined,” or “attached” to another component, the certain component may be connected, coupled, joined, or attached directly to another component, but it should be understood that still another component may be interposed between the components that may be connected, coupled, joined, or attached indirectly unless stated specifically otherwise.

When a component or a layer is described as “coming into contact with” or “overlapping” another component or layer, the component or the layer may come into direct contact with or directly overlap another component or layer, but it should be understood that still another component may be interposed between the components that may come into indirect contact with and indirectly overlap each other unless stated specifically otherwise.

It should be understood that the term “at least one” includes any combination of one or more of associated components. For example, the term “at least one of first, second, and third components” may include not only the first, second, or third component, but also any combination of two or more of the first, second, and third components.

The terms “first direction,” “second direction,” “third direction,” “X-axis direction,” “Y-axis direction,” and “Z-axis direction” should not be construed as merely the geometric relationship in which the relationship therebetween is perpendicular and may refer to a wider directionality within the range in which the configuration of the present disclosure may act functionally.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these implementations may be provided so that this disclosure may be sufficiently thorough and complete to assist those skilled in the art to fully understand the scope of the present disclosure. Furthermore, the present disclosure is only defined by scopes of claims.

Features of various implementations of the present disclosure may be coupled or combined partially or entirely, various technological interworking and driving are made possible, and the implementations may be implemented independently of each other or implemented together in an associated relationship.

Hereinafter, various implementations of the present disclosure will be described in detail with reference to the accompanying drawings.

The display apparatus according to the implementation of the present disclosure may be included in various devices or electronic devices. Various devices or electronic devices including the display apparatus according to the implementation of the present disclosure may include mobile devices, laptop computers, and monitors or TVs, but the implementations of the present disclosure are not limited thereto.

The display apparatus according to the implementation of the present disclosure may be applied to wearable apparatuses such as smart watches, watch phones, etc.

Each of the wearable apparatus, the mobile device, the laptop computer, and the monitor or TV may include a case, a display panel, and a display apparatus.

For example, the display apparatus according to the implementation of the present disclosure may be applied to mobile devices, video phones, smart watches, watch phones, wearable apparatuses, foldable devices, rollable apparatuses, bendable apparatuses, flexible apparatuses, curved apparatuses, sliding apparatuses, variable apparatuses, electronic notebooks, electronic books, portable multimedia players (PMPs), personal digital assistants (PDAs), MP3 players, mobile medical apparatuses, desktop PCs, laptop PCs, netbook computers, workstations, navigation systems, vehicle display apparatuses, theater display apparatuses, televisions, wallpaper apparatuses, signage apparatuses, game apparatuses, notebook computers, monitors, cameras, camcorders, home appliances, etc.

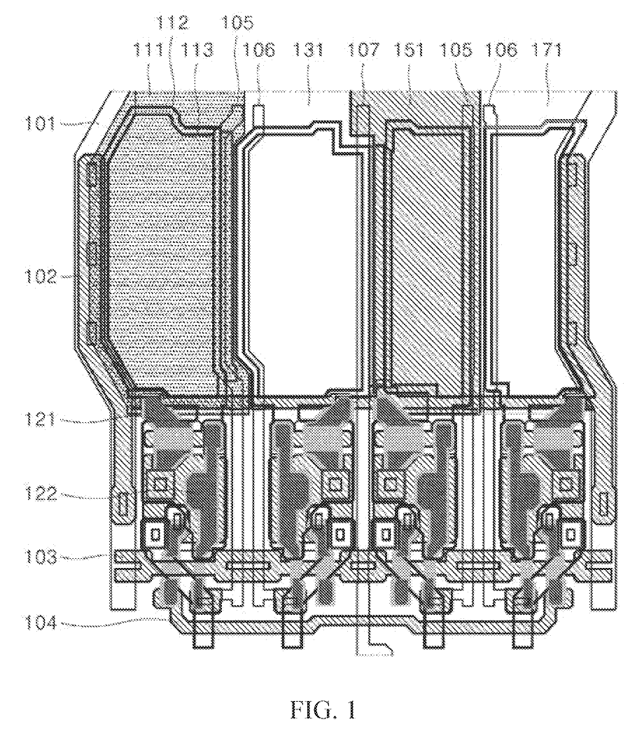

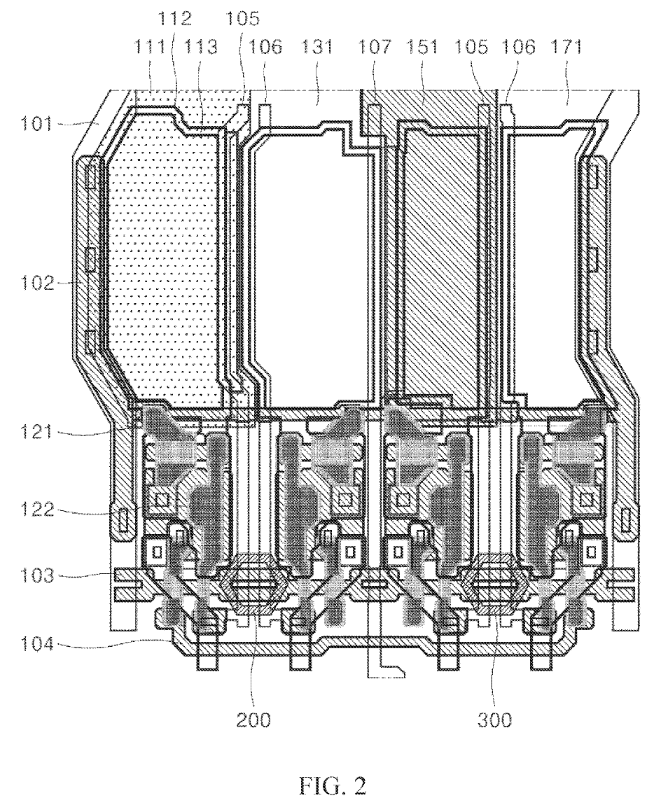

FIG. 1 is a plan view showing a pixel configuration of a display apparatus according to an implementation of the present disclosure. FIG. 2 is a plan view showing a pixel configuration in which a repair circuit is disposed according to the implementation of the present disclosure.

Referring to FIGS. 1 and 2, a display apparatus according to an implementation of the present disclosure may include a plurality of sub-pixels 111, 131, 151, and 171, a plurality of data lines 105 and 106, a scan line 103, and repair circuits 200 and 300.

In addition, the display apparatus according to the implementation of the present disclosure may further include high-potential power lines (EVDD) 101 and 102, reference voltage lines (Ref) 104 and 107, and active layers (ACT) 121 and 122.

The plurality of sub-pixels 111, 131, 151, and 171 may be disposed adjacent to each other in a first direction (a horizontal direction). The plurality of sub-pixels 111, 131, 151, and 171 may be formed of organic light-emitting diodes capable of displaying R (Red), G (Green), B (Blue), and W (White) colors. This is one implementation for describing the present disclosure, and the plurality of sub-pixels 111, 131, 151, and 171 may be formed of organic light-emitting diodes capable of displaying R, G, and B colors.

The plurality of sub-pixels 111, 131, 151, and 171 may emit light of different colors. For example, the plurality of sub-pixels may include a first sub-pixel 111 emitting red (R) light, a second sub-pixel 131 emitting green (G) light, a third sub-pixel 151 emitting blue (B) light, and a fourth sub-pixel 171 emitting white (W) light.

The scan line 103 may be disposed to extend in the first direction (the horizontal direction) below the plurality of sub-pixels 111, 131, 151, and 171. The scan line 103 may be used to apply scan signals, that is, gate voltages, to the plurality of sub-pixels 111, 131, 151, and 171.

The plurality of data lines 105 and 106 may be disposed to extend in a second direction (a vertical direction) between the plurality of neighboring sub-pixels 111 to 131 and 151 to 171.

The repair circuits 200 and 300 may be disposed at locations where the plurality of data lines 105 and 106 intersect the scan line 103, respectively.

The plurality of sub-pixels 111, 131, 151, and 171 may be electrically connected to the scan lines 103 disposed thereunder. Accordingly, the plurality of sub-pixels 111, 131, 151, and 171 may receive the scan signals through the scan lines 103.

The plurality of sub-pixels 111, 131, 151, and 171 may be electrically connected to the plurality of data lines 105 and 107 disposed between the neighboring sub-pixels 111 to 131 and 151 to 171. Accordingly, the plurality of sub-pixels 111, 131, 151, and 171 may receive data voltages through the plurality of data lines 105 and 107.

A display panel according to the implementation of the present disclosure may be configured such that power lines 101 and 107 are disposed to extend in the second direction outside or between the plurality of sub-pixels 111, 131, 151, and 171.

The power lines 101 and 107 may include first power lines 101 and 102 along which a pixel driving voltage (EVDD) is applied to the plurality of sub-pixels 111, 131, 151, and 171, and a second power line 107 along which a reference voltage (Vref) is applied to the plurality of sub-pixels 111, 131, 151, and 171. Here, the pixel driving voltage (EVDD) may be the high-potential power supply voltage (EVDD), the first power lines 101 and 102 may be the high-potential power lines 101 and 102, and the second power line 107 may be reference voltage lines 104 and 107.

In the plan views of FIGS. 1 and 2, the high-potential power lines 101 and 102 may be disposed on an outer edge of the first sub-pixel 111 in a left direction, and the active layers 121 and 122 may be disposed below the plurality of sub-pixels 111, 131, 151, and 171. One of the reference voltage lines 104 and 107 may be disposed to extend in the second direction (the longitudinal direction) between the second sub-pixel 131 and the third sub-pixel 151, and the other may be disposed below the scan line 103.

The first power lines 101 and 102 and the second power line 107 may be electrically connected to the plurality of sub-pixels 111, 131, 151, and 171.

The plurality of sub-pixels 111, 131, 151, and 171 may include at least one of the first sub-pixel 111 of red (R), the second sub-pixel 131 of green (G), the third sub-pixel 151 of blue (B), and the fourth sub-pixel 171 of white (W).

The display panel according to the implementation of the present disclosure may be configured such that the plurality of sub-pixels 111, 131, 151, and 171 are disposed in a left-right mirror symmetrical structure with respect to a vertical axis, which is along the second direction. A plurality of neighboring sub-pixels may share a sub-pixel of white color. One sub-pixel may include a pixel circuit and a light-emitting area that is connected to the pixel circuit and emits light of a corresponding color. For example, the first sub-pixel 111 may have a first light-emitting area, the second sub-pixel 131 may have a second light-emitting area, the third sub-pixel 151 may have a third light-emitting area, and the fourth sub-pixel 171 may have a fourth light-emitting area.

In the plan views of FIGS. 1 and 2, each of the plurality of sub-pixels 111, 131, 151, and 171 may include an anode electrode 112 and a bank layer (BANK) 113. The anode electrode 112 of the corresponding sub-pixel may be disposed in the light-emitting area of each sub-pixel. The pixel circuits are connected to the anode electrode 112 of the corresponding light-emitting area. When current is generated from a driving element of the pixel circuit, the light-emitting area of each sub-pixel may emit light.

A plurality of adjacent sub-pixels may be driven by a hybrid method. For example, when a first pixel and a second pixel are adjacent to each other and the first pixel is driven with the fourth sub-pixel, the second pixel may be driven with the third sub-pixel. When the second pixel is driven with the fourth sub-pixel, the first pixel may be driven with the third sub-pixel.

Light-emitting area distributions of color-specific sub-pixels may be appropriately selected in consideration of color reproducibility and high brightness. For example, an image or display model that prioritizes high brightness over color reproducibility may increase an area of the fourth light-emitting area and increase driving voltages of three sub-pixels excluding the white sub-pixel. In the case of a display model that prioritizes a pure color, for example, the fourth light-emitting area may be decreased. When brightness is increased, for example, the fourth light-emitting area may be increased.

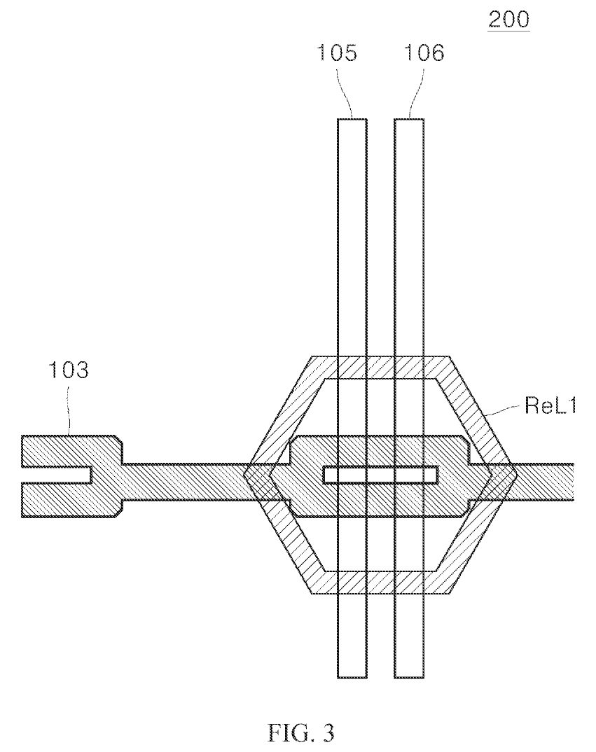

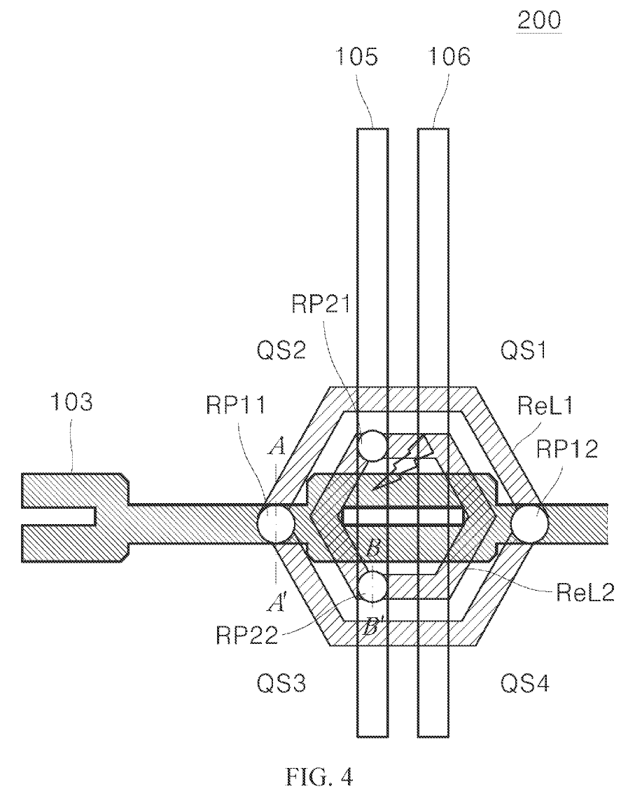

FIG. 3 is a view showing an example of a configuration of the repair circuit according to the implementation of the present disclosure. FIG. 4 is a view showing an example of a configuration of a repair circuit according to another implementation of the present disclosure.

Referring to FIGS. 3 and 4, the repair circuit 200 according to the implementation of the present disclosure may include a first repair line ReL1 and a second repair line ReL2.

The first repair line ReL1 may electrically connect two defective or disconnected points RP11 and RP12 of the scan line 103. That is, the first repair line ReL1 electrically connects two points of two sides of the disconnected point by bypassing the defective or disconnected points of the scan line 103.

The second repair line ReL2 may electrically connect two defective or disconnected points RP21 and RP22 of the data line 105. That is, the second repair line ReL2 electrically connects two points of two sides of the disconnected point by bypassing the defective or disconnected points of the data line 105.

The first repair line ReL1 and the second repair line ReL2 may be disposed on the same layer. The first repair line ReL1 and the second repair line ReL2 may be disposed on a different layer from the scan line 103 or the data line 105. The first repair line ReL1 and the second repair line ReL2 may be disposed on the same layer as the active layer of each sub-pixel.

Each of the first repair line ReL1 and the second repair line ReL2 may include a transparent conductive material. For example, each of the first repair line ReL1 and the second repair line ReL2 may be formed of at least one transparent conductive material among indium tin oxide (ITO), indium zinc oxide (IZO), and indium gallium zinc oxide (IGZO), but the implementations of the present disclosure are not limited thereto.

In FIGS. 3 and 4, the first repair line ReL1 and the second repair line ReL2 may be disposed not to overlap each other.

In FIGS. 3 and 4, in the display apparatus, a first quadrant QS1 to a fourth quadrant QS4 may be formed when the scan line 103 and the data lines 105 and 106 intersect each other.

The display apparatus may be configured such that the first quadrant QS1 and a second quadrant QS2 are positioned above the scan line 103 and a third quadrant QS3 and the fourth quadrant QS4 are positioned below the scan line 103 on both sides of the data lines 105 and 106.

The scan line 103 may be formed of a conductive material, for example, a metal material. The metal material may be formed of one of molybdenum (Mo), aluminum (Al), chromium (Cr), gold (Au), titanium (Ti), nickel (Ni), neodymium (Nd), and copper (Cu), or an alloy thereof.

The first repair line ReL1 may have the same material as the material of the scan line 103. The first repair line ReL1 may be formed of a metal material. The first repair line ReL1 may be formed of, for example, one of molybdenum (Mo), aluminum (Al), chromium (Cr), gold (Au), titanium (Ti), nickel (Ni), neodymium (Nd), and copper (Cu), or an alloy thereof.

The first repair line ReL1 may be formed to extend from a first repair point RP11 to a second repair point RP12 via the second quadrant QS2 and the first quadrant QS1.

The first repair point RP11 and the second repair point RP12 may be points where laser light is irradiated. For example, the first repair point RP11 and the second repair point RP12 may be points where laser light of a temperature capable of melting the first repair line ReL1 is irradiated.

In addition, the first repair line ReL1 may be formed to extend from the first repair point RP11 to the second repair point RP12 via the third quadrant QS3 and the fourth quadrant QS4.

The first repair line ReL1 may have a hexagonal shape passing through the first quadrant QS1 to the fourth quadrant QS4. However, the present disclosure is not limited thereto. For example, the first repair line ReL1 may have various shapes such as a circle, a quadrangle, an octagon, a rhombus, a trapezoid, etc.

The second repair line ReL2 may be formed to extend from the third repair point RP21 to the fourth repair point RP22 via the second quadrant QS2 and the third quadrant QS3.

The data line 105 may be formed of a conductive material, for example, a metal material. The metal material may be formed of one of molybdenum (Mo), aluminum (Al), chromium (Cr), gold (Au), titanium (Ti), nickel (Ni), neodymium (Nd), and copper (Cu), or an alloy thereof.

The second repair line ReL2 may be formed of the same material as the material of the data line 105. The second repair line ReL2 may be formed of, for example, one of molybdenum (Mo), aluminum (Al), chromium (Cr), gold (Au), titanium (Ti), nickel (Ni), neodymium (Nd), and copper (Cu), or an alloy thereof.

The third repair point RP21 and the fourth repair point RP22 may be points where laser light is irradiated. For example, the third repair point RP21 and the fourth repair point RP22 may be points where laser light of a temperature capable of melting the second repair line ReL2 is irradiated.

In addition, the second repair line ReL2 may be formed to extend from the third repair point RP21 to the fourth repair point RP22 via the first quadrant QS1 and the fourth quadrant QS4.

The second repair line ReL2 may have a hexagonal shape passing through the first quadrant QS1 to the fourth quadrant QS4. However, the present disclosure is not limited thereto. For example, the second repair line ReL2 may have various shapes such as a circle, a quadrangle, an octagon, a rhombus, a trapezoid, etc.

The first repair line ReL1 may have a larger length than the second repair line ReL2. An area of the shape of the first repair line ReL1 may be larger than an area of the shape of the second repair line ReL2.

The first repair line ReL1 may have a smaller length than the second repair line ReL2. The area of the shape of the first repair line ReL1 may be smaller than the area of the shape of the second repair line ReL2.

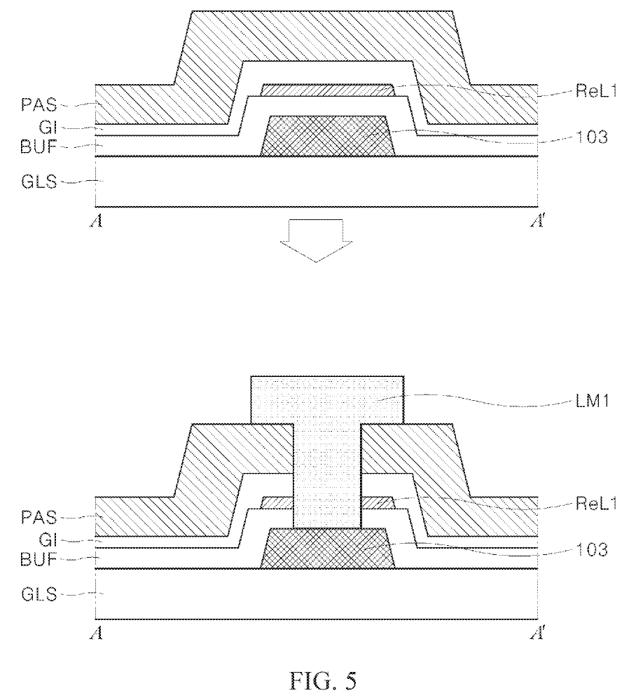

FIG. 5 is a view showing an example of a cross-sectional structure of the repair circuit according to the implementation of the present disclosure.

Referring to FIG. 5, the repair circuit according to the implementation of the present disclosure may include the scan line 103 on a substrate GLS, a buffer layer BUF on the substrate GLS and the scan line 103, the repair line ReL1 on the buffer layer BUF, a gate insulating layer GI on the buffer layer BUF and the repair line ReL1, and a passivation layer PAS on the gate insulating layer GI.

That is, when an active layer is formed on the buffer layer BUF in the active area, the repair circuit has the repair line ReL1 formed on the buffer layer BUF. Accordingly, the repair line ReL1 may be formed on the same layer as the active layer of each sub-pixel.

Here, an example in which the repair line ReL1 is the first repair line ReL1 is described, but the implementations of the present disclosure are not limited thereto, and the second repair line ReL2 may be formed.

The substrate GLS may be a plastic film or a glass substrate, but is not limited thereto.

The scan line 103 may be formed of a conductive metal material.

The buffer layer BUF may be formed of a plurality of inorganic films alternately stacked. For example, the buffer layer BUF may be formed of a multi-film in which one or more inorganic films of a silicon oxide film (SiOₓ), a silicon nitride film (SiNₓ), a silicon nitride oxide (SiON), and a silicon dioxide (SiO2) are alternately stacked. Alternatively, the buffer layer BUF may be formed of a single film in which one inorganic film of a silicon oxide film (SiOₓ), a silicon nitride film (SiNₓ), a silicon nitride oxide (SiON), and a silicon dioxide (SiO₂) is stacked.

The repair line ReL1 may be formed of a transparent conductive material. In addition, the repair line ReL1 may be formed of the same material as the scan line 103. Alternatively, the repair line ReL1 may be formed of the same material as the data line 105.

The repair line ReL1 may be formed on the same layer as the active layer of each sub-pixel. The active layer may be formed of a silicon-based semiconductor material or an oxide-based semiconductor material.

A gate insulating layer GI may be formed of an inorganic film, such as a silicon oxide film (SiOₓ), a silicon nitride film (SiNₓ), or a multi-film thereof.

The passivation layer PAS may be formed of an organic film, such as an acrylic resin, an epoxy resin, a phenolic resin, a polyamide resin, a polyimide resin, etc.

The repair circuit having the stacked structure of FIG. 5 is formed such that laser light is irradiated to each of the first repair point RP11 and the second repair point RP12 so that the first repair line ReL1 is melted at each of the first repair point RP11 and the second repair point RP12 to form a first connection electrode (laser melting line) LM1.

In this case, a portion of the scan line 103 is also melted by the laser light at the first repair point RP11 and the second repair point RP12 to form the first connection electrode LM1.

Accordingly, the first connection electrode LM1 formed by the laser light connects the first repair line ReL1 to the scan line 103 at each of the first repair point RP11 and the second repair point RP12.

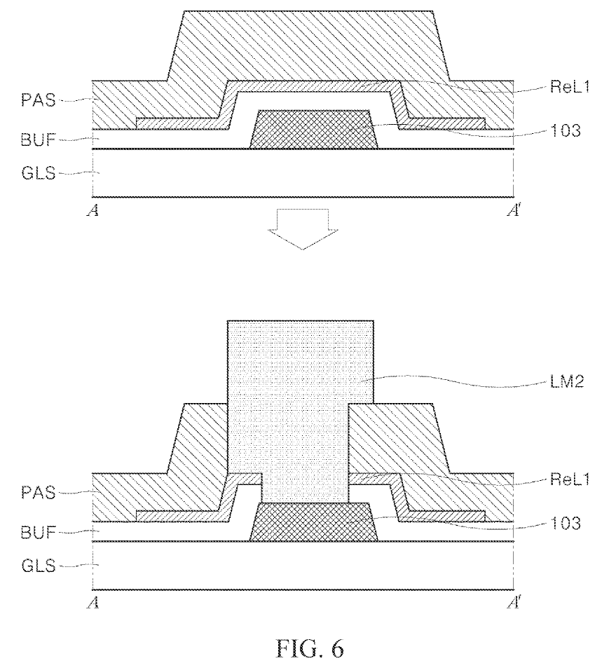

FIG. 6 is a view showing an example of a cross-sectional structure of the repair circuit according to another implementation of the present disclosure.

Referring to FIG. 6, a repair circuit according to another implementation of the present disclosure has the same stacked structure as FIG. 5, and an example in which the gate insulating layer GI is removed and the first repair line ReL1 disposed on the buffer layer BUF is disposed to have a larger width than the scan line 103.

Even in this case, when laser light is irradiated on the first repair line ReL1 at the first repair point RP11 and the second repair point RP12, the first repair line ReL1 is melted by the laser light to form a second connection electrode LM2.

In this case, a portion of the scan line 103 is also melted by the laser light at the first repair point RP11 and the second repair point RP12 to form the second connection electrode LM2.

Accordingly, the second connection electrode LM2 formed by the laser light connects the first repair line ReL1 to the scan line 103 at each of the first repair point RP11 and the second repair point RP12.

In the implementation of FIGS. 5 and 6, an example in which the scan line 103 is disposed on the substrate GLS is described, but the present disclosure is not limited thereto, and for example, the data line 105 may be disposed on the substrate GLS, and the data line 105 and the repair line ReL1 may be connected by laser light.

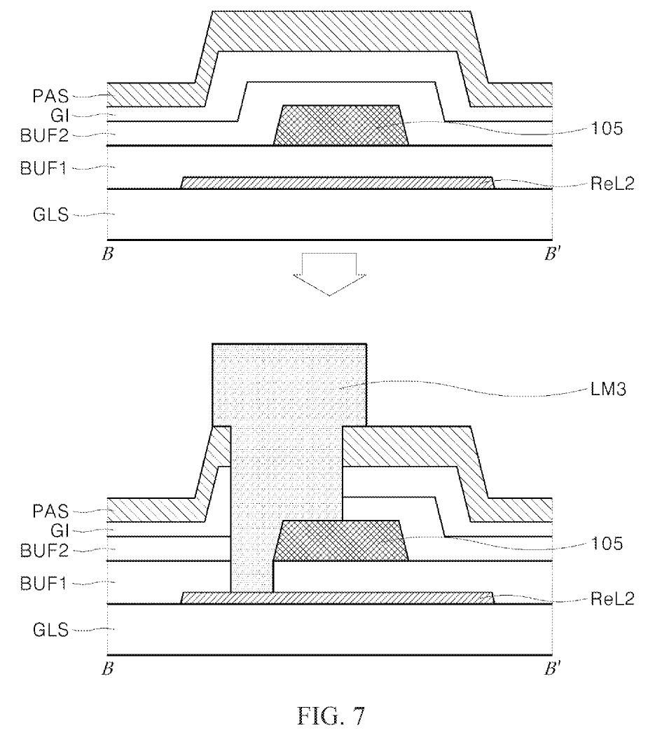

FIG. 7 is a view showing an example of a cross-sectional structure of a repair circuit according to still another implementation of the present disclosure.

Referring to FIG. 7, a repair circuit according to another implementation of the present disclosure may include the repair line ReL2 on the substrate GLS, a first buffer layer BUF1 on the substrate GLS and the repair line ReL2, the data line 105 on the first buffer layer BUF1, a second buffer layer BUF2 on the first buffer layer BUF1 and the data line 105, the gate insulating layer GI on the second buffer layer BUF2, and the passivation layer PAS on the gate insulating layer GI.

In the case of FIG. 7, the repair circuit has the repair line ReL2 formed between the substrate GLS and the first buffer layer BUF1. Here, the repair line ReL2 is referred to as the second repair line ReL2.

Even in this case, when laser light is irradiated on the second repair line ReL2 at the first repair point RP11 and the second repair point RP12, the second repair line ReL2 is melted by the laser light to form a third connection electrode LM3.

In this case, a portion of the data line 105 is also melted by the laser light at the first repair point RP11 and the second repair point RP12 to form the third connection electrode LM3.

Accordingly, the third connection electrode LM3 formed by the laser light connects the second repair line ReL2 to the data line 105 at each of the first repair point RP11 and the second repair point RP12.

In the implementation of FIG. 7, an example in which the data line 105 is disposed on the first buffer layer BUF1 is described, but the present disclosure is not limited thereto, and for example, the scan line 103 may be disposed on the first buffer layer BUF1, and the scan line 103 and the repair line ReL2 may be connected by laser light.

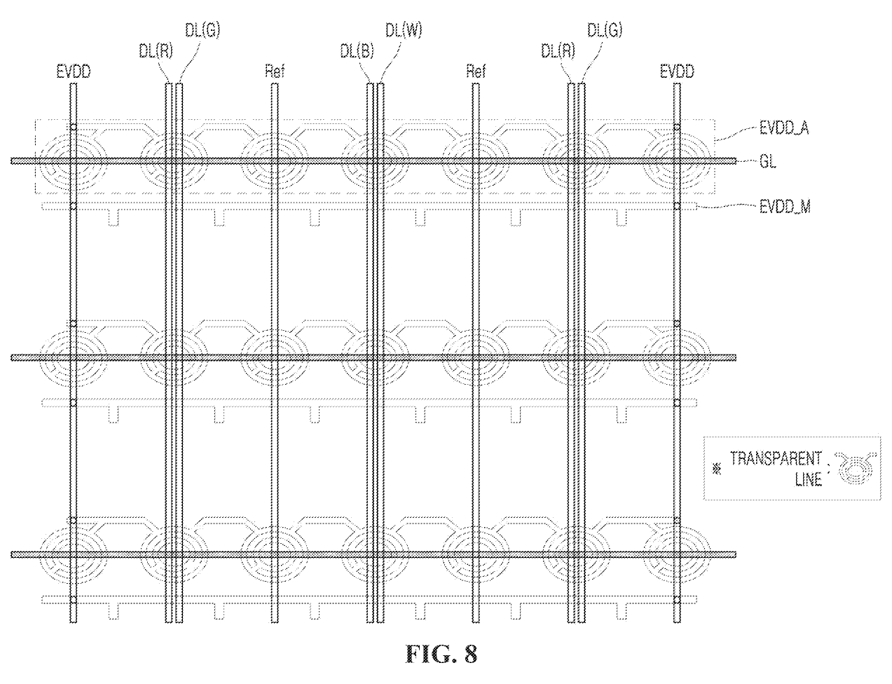

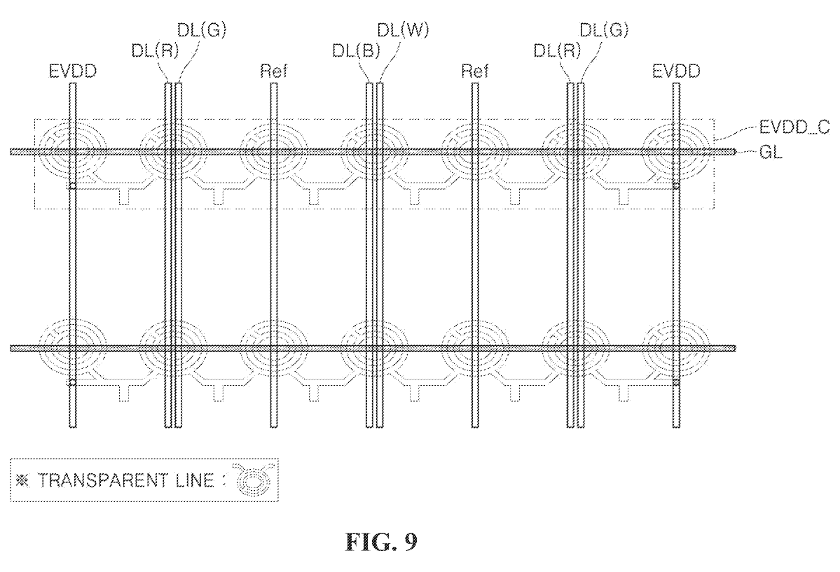

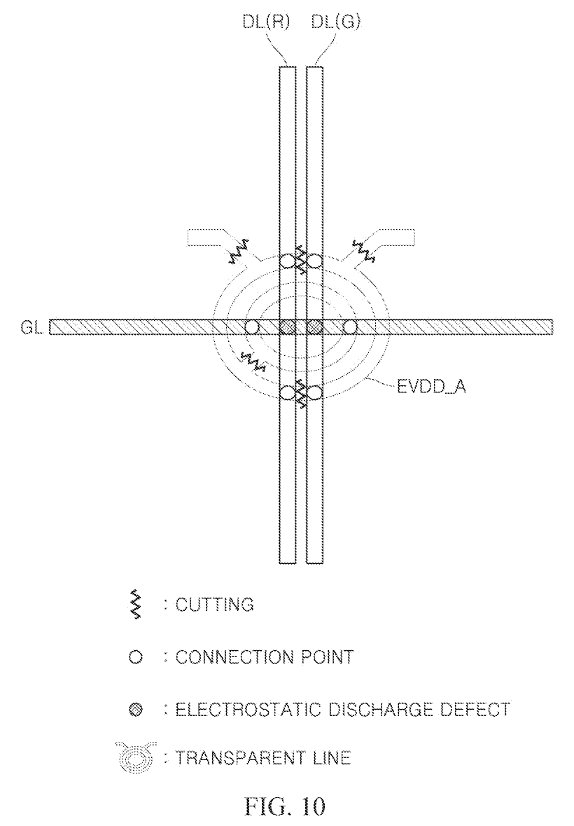

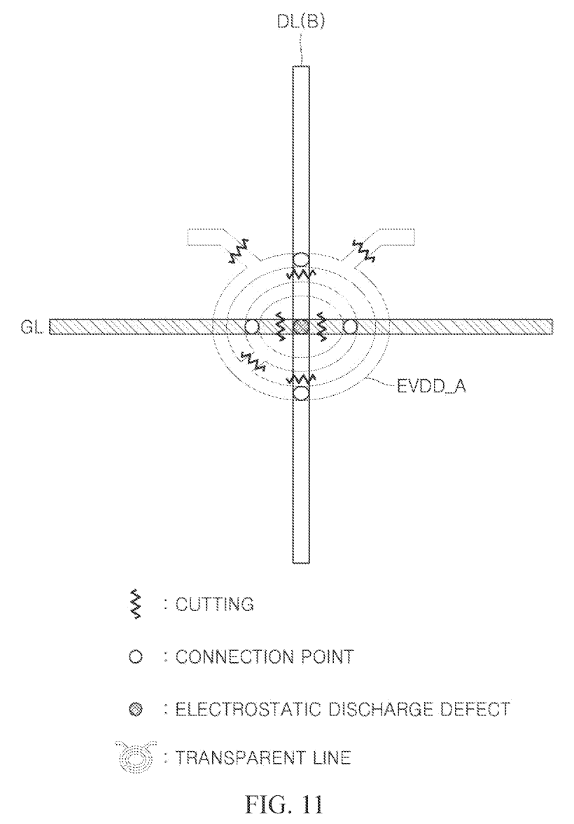

FIG. 8 is a view showing an example in which an auxiliary power line is used as a repair line for the repair circuit according to still another implementation of the present disclosure. FIG. 9 is a view showing an example in which a main power line is used as a repair line for the repair circuit according to still another implementation of the present disclosure. FIG. 10 is a view showing an example in which a gate line and data lines that are opened due to an electrostatic discharge defect are repaired through the auxiliary power line according to the implementation of the present disclosure. FIG. 11 is a view showing an example in which a gate line and a data line that are shorted due to an electrostatic discharge defect are repaired through the auxiliary power line according to the implementation of the present disclosure.

Referring to FIG. 8, in a display apparatus according to still another implementation of the present disclosure, a main power line EVDD_M parallel to a gate line GL extending horizontally with respect to each sub-pixel may be disposed, and power lines EVDD, data lines DL(R), DL(G), DL(B), and DL(W)), and reference voltage lines Ref extending vertically with respect to each sub-pixel may be disposed.

A repair circuit for such a structure may have a structure in which auxiliary power lines EVDD_A intersecting and overlapping the power lines EVDD, the data lines DL(R), DL(G), DL(B), and DL(W), and the reference voltage lines Ref in addition to the gate line GL are disposed to extend horizontally.

In this case, the auxiliary power line EVDD_A may operate as a repair line and have a spiral shape for each part intersecting and overlapping each line. However, the present disclosure is not limited thereto. For example, the auxiliary power line EVDD_A may have various shapes such as a circle, a quadrangle, a pentagon, a hexagon, a diamond, a ladder, etc.

The auxiliary power line EVDD_A has a structure in which a plurality of spiral shapes are disposed and adjacent spiral shapes are connected through a single line.

The main power line EVDD_M and the auxiliary power line EVDD_A may be, for example, high-potential power lines that supply high-potential voltage.

The auxiliary power line EVDD_A may be disposed above the main power line EVDD_M. The main power line EVDD_M is used to supply the high-potential power voltage EVDD, but the auxiliary power line EVDD_A is not used to supply the high-potential power voltage EVDD but is used to repair a disconnection of each line and the like.

The auxiliary power line EVDD_A as a repair line may be formed of a transparent conductive material. For example, the auxiliary power line EVDD_A may be formed of at least one transparent conductive material among ITO, IZO, and IGZO, but the implementations of the present disclosure are not limited thereto.

The auxiliary power line EVDD_A may be disposed such that the power lines EVDD, the data lines DL(R), DL(G), DL(B), and DL(W), and the reference voltage lines Ref are positioned at the center of each spiral shape.

Referring to FIG. 9, in the display apparatus according to still another implementation of the present disclosure, the gate lines GL extending horizontally with respect to each sub-pixel may be disposed to intersect the power lines EVDD, the data lines DL(R), DL(G), DL(B), and DL(W), and the reference voltage lines Ref, which extend vertically with respect to each sub-pixel.

A repair circuit for such a structure may have a structure in which a connection power line EVDD_C is disposed to extend horizontally on each of points where the power lines EVDD, the data lines DL(R), DL(G), DL(B), and DL(W), the reference voltage lines Ref intersect the gate lines GL.

The power lines EVDD, the data lines DL(R), DL(G), DL(B), and DL(W), and the reference voltage lines Ref may be referred to as vertical lines.

The connection power line EVDD_C may operate as a high-potential power line that supplies high-potential power voltage to each sub-pixel and also operate as a repair line, and may have a spiral shape on each of points where vertical lines intersect the gate lines.

The connection power line EVDD_C may operate as a high-potential power line by being connected to the high-potential power line EVDD at the outermost left end and the high-potential power line EVDD at the outermost right end.

The connection power line EVDD_C may have a structure in which a plurality of spiral shapes are disposed and neighboring spiral shapes are connected through a single line.

The connection power line EVDD_C may operate as a repair line by having the spiral shapes disposed on each of the points where the vertical lines intersect the gate lines GL and connecting a vertical line on which disconnection occurs through the spiral line.

Referring to FIG. 10, a spiral auxiliary power line EVDD_A may be disposed as a repair line on points where one gate line GL intersects the plurality of data lines DL(R) and DL(G). Here, the spiral auxiliary power line EVDD_A is a transparent line.

The plurality of data lines may be, for example, one data line DL(R) of a red sub-pixel and the other data line DL(G) of a green sub-pixel.

In this case, an open due to an electrostatic discharge detect may occur at two points where one gate line GL intersects the plurality of data lines DL(R) and DL(G). Accordingly, one gate line GL may be opened at a defective point, and the two data lines DL(R) and DL(G) may also be opened at each defective point.

In this case, for the two opened points, upper and lower points of the spiral auxiliary power line EVDD_A, which overlap the data lines DL(R) and DL(G), may be melted by irradiating laser light so that upper and lower points of the opened data lines DL(R) and DL(G) may be connected through the auxiliary power line EVDD_A. Here, other portions of the auxiliary power line EVDD_A, which are connected to the high-potential power line, are cut.

In addition, for the two opened points, left and right points of the spiral auxiliary power line EVDD_A, which overlap the gate line GL, are melted by irradiating laser light so that left and right points of the opened gate line GL may be connected through the auxiliary power line EVDD_A.

Referring to FIG. 11, the spiral auxiliary power line EVDD_A may be disposed on a portion where one gate line GL intersects one data line DL(B) as a repair line. Here, the spiral auxiliary power line EVDD_A is a transparent line.

One data line may be, for example, the data line DL(B) of a blue sub-pixel.

In this case, a short due to an electrostatic discharge defect may occur at a point where one gate line GL intersects one data line DL(B). Accordingly, the gate line GL and the data line DL(B) that intersect each other may come into contact with each other.

In this case, for a shorted point, upper and lower points of the spiral auxiliary power line EVDD_A, which overlap the data line DL(B), are melted by irradiating laser light so that upper and lower points of the shorted data line DL(B) may be connected through the auxiliary power line EVDD_A. In addition, upper and lower sides of the defective point of the data line DL(B) are cut to be electrically disconnected. Here, other portions of the auxiliary power line EVDD_A, which are connected to the high-potential power line, are also cut.

In addition, for the shorted point, left and right points of the spiral auxiliary power line EVDD_A, which overlap the gate line GL, are melted by irradiating laser light so that left and right points of the shorted gate line GL may be connected through the auxiliary power line EVDD_A. In this case, left and right sides of the defective point of the gate line GL are cut to be electrically disconnected. Here, other portions of the auxiliary power line EVDD_A, which are connected to the high-potential power line, are also cut.

As described above, according to still another implementation of the present disclosure, the auxiliary power line may be disposed in each sub-pixel, and when a gate line, a data line, etc. are opened or shorted, the auxiliary power line may be used as a repair line by connecting the two opened or shorted points through the auxiliary power line.

The display apparatus according to the implementation of the present disclosure may include a display panel having the above structure and further include a scan (gate) driver, a data driver, and a timing controller.

That is, the display apparatus may include a plurality of sub-pixels adjacent to each other in a first direction, a scan line disposed to extend in the first direction below the plurality of sub-pixels, a plurality of data lines disposed to extend in a second direction between the plurality of adjacent sub-pixels, and repair circuits disposed at points where the plurality of data lines intersect the scan line.

The scan driver provides a scan (gate) signal to the plurality of sub-pixels.

The data driver provides a data signal to the plurality of sub-pixels.

The timing controller controls the scan driver and the data driver.

The timing controller may simultaneously drive adjacent pixels, for example, with a third sub-pixel, when an input image is a pure color or has chroma higher than a predetermined reference value based on an analysis of the chroma of the input image. In this case, the sub-pixel of white color is not driven.

The display apparatus according to the implementations of the present disclosure may be a liquid crystal display apparatus or the like or may be a light-emitting display apparatus in which a display panel emits light by itself. When the display apparatus according to the implementations of the present disclosure is a self-emitting display apparatus, each of the plurality of sub-pixels may include a light-emitting element.

For example, the display apparatus according to the implementations of the present disclosure may be an organic light-emitting diode (OLED) display apparatus in which a light-emitting element is implemented as an OLED. As another example, the display apparatus according to the implementations of the present disclosure may be an inorganic light-emitting display apparatus in which a light-emitting element is implemented as an inorganic material-based light-emitting diode. As still another example, the display apparatus according to the implementations of the present disclosure may be a quantum dot display apparatus in which a light-emitting element is implemented as quantum dots that are semiconductor crystals that emits light by themselves.

The structure of each of the plurality of sub-pixels may vary depending on the type of the display apparatus. For example, when the display apparatus is a self-luminous display apparatus in which a sub-pixel emits light by itself, each sub-pixel may include a light-emitting element that emits light by itself, one or more transistors, and one or more capacitors.

To provide both an image display function and a touch sensing function, the display apparatus according to the implementations of the present disclosure may include a touch sensor, and a touch sensing circuit for detecting whether a touch has been caused by a touch object, such as a finger, a pen, etc. or detecting a touch position by sensing the touch sensor.

The touch sensing circuit may include a touch driving circuit for driving and sensing the touch sensor and generating and outputting touch sensing data, a touch controller for sensing the occurrence of touch or detecting the touch position using the touch sensing data, etc.

The touch sensor may include a plurality of touch electrodes. The touch sensor may further include a plurality of touch lines for electrically connecting a plurality of touch electrodes to the touch driving circuit.

The touch sensor may be present outside or inside the display panel in the form of a touch panel.

When the touch sensor is present outside the display panel in the form of a panel, the touch sensor is referred to as an external type touch sensor. When the touch sensor is of an external type, the touch panel and the display panel may be manufactured separately and coupled during an assembly process. The external type touch panel may include a touch panel substrate and a plurality of touch electrodes disposed on the touch panel substrate.

When the touch sensor is present inside the display panel, the touch sensor may be formed on a substrate along with signal lines, electrodes, etc. related to display driving during a manufacturing process of the display panel.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

When the touch sensing circuit performs touch sensing using the self-capacitance sensing method, the touch sensing circuit may perform the touch sensing based on a capacitance between each touch electrode and the touch object (e.g., a finger or a pen).

According to the self-capacitance sensing method, each of the plurality of touch electrodes may operate as both a driving touch electrode and a sensing touch electrode. The touch driving circuit may drive all or some of the plurality of touch electrodes and sense all or some of the plurality of touch electrodes.

When the touch sensing circuit performs the touch sensing using the mutual-capacitance sensing method, the touch sensing circuit may perform the touch sensing based on the capacitance between the touch electrodes.

According to the mutual-capacitance sensing method, the plurality of touch electrodes are divided into driving touch electrodes and sensing touch electrodes. The touch driving circuit may drive the driving touch electrodes and sense the sensing touch electrodes.

The touch driving circuit and touch controller included in the touch sensing circuit may be implemented as separate devices or implemented as a single device. In addition, the touch driving circuit and a data driving circuit may be implemented as separate devices or implemented as a single device.

According to the implementations of the present disclosure, even when disconnection occurs in a data line or scan line due to electrostatic discharge, the disconnected data line or scan line may be repaired through a repair circuit, thereby improving the quality of the product. It is possible to provide a display apparatus capable of securing the reliability of the product by improving the quality of the product.

A display apparatus according to various implementations of the present disclosure may be described as follows.

According to one implementation of the present disclosure, there may be provided a display apparatus including a plurality of sub-pixels adjacent to each other in a first direction, a scan line disposed to extend in the first direction below the plurality of sub-pixels, a plurality of data lines disposed to extend in a second direction between the plurality of adjacent sub-pixels, and repair circuits disposed at points where the plurality of data lines intersect the scan line.

According to some implementations of the present disclosure, the repair circuit may include a first repair line for connecting two defective or disconnected points of the scan line, and a second repair line for connecting two defective or disconnected points of the data line.

According to some implementations of the present disclosure, each of the first repair line and the second repair line may include a transparent conductive material.

According to some implementations of the present disclosure, the first repair line and the second repair line may include at least one of indium tin oxide (ITO), indium zinc oxide (IZO), and indium gallium zinc oxide (IGZO).

According to some implementations of the present disclosure, the first repair line and the second repair line may be disposed on the same layer.

According to some implementations of the present disclosure, the first repair line and the second repair line may be disposed on a different layer from the scan line or the data line.

According to some implementations of the present disclosure, the first repair line and the second repair line may be disposed on the same layer as an active layer of the sub-pixel.

According to some implementations of the present disclosure, the first repair line and the second repair line may be disposed not to overlap each other.

According to some implementations of the present disclosure, the first repair line may have the same material as the scan line.

According to some implementations of the present disclosure, the second repair line may have the same material as the data line.

According to some implementations of the present disclosure, the first repair line and the second repair line may be formed of one of molybdenum (Mo), aluminum (Al), chromium (Cr), gold (Au), titanium (Ti), nickel (Ni), neodymium (Nd), and copper (Cu), or an alloy thereof.

According to some implementations of the present disclosure, the repair circuit may include a scan line on a substrate, a buffer layer on the substrate and the scan line, a repair line on the buffer layer, a gate insulating layer on the buffer layer and the repair line, and a passivation layer on the gate insulating layer.

According to some implementations of the present disclosure, the repair circuit may include a repair line on a substrate, a first buffer layer on the substrate and the repair line, a data line on the first buffer layer, a second buffer layer on the first buffer layer and the data line, a gate insulating layer on the second buffer layer, and a passivation layer on the gate insulating layer.

A display apparatus according to various implementations of the present disclosure may be described as follows.

According to another implementation of the present disclosure, there may be provided a display apparatus including a gate line extending horizontally with respect to each sub-pixel, a main power line disposed parallel to the gate line, a plurality of vertical lines extending vertically with respect to each sub-pixel, and an auxiliary power line disposed horizontally to overlap each of points where the plurality of vertical lines intersect the gate line, in which the auxiliary power line may have a spiral shape on each overlapping portion.

According to some implementations of the present disclosure, the plurality of vertical lines may include power lines EVDD, data lines DL(R), DL(G), DL(B), and DL(W), and reference voltage lines Ref.

According to some implementations of the present disclosure, the auxiliary power line may be formed of a transparent conductive material.

According to some implementations of the present disclosure, the auxiliary power line may be disposed above the main power line.

Meanwhile, according to still another implementation of the present disclosure, there may be provided a display apparatus including a gate line extending horizontally with respect to each sub-pixel, a plurality of vertical lines extending vertically with respect to each sub-pixel, and a connection power line disposed to extend horizontally to overlap each of points where the plurality of vertical lines intersect the gate line, in which the connection power line may have a spiral shape on each overlapping portion

According to some implementations of the present disclosure, the connection power line may be formed of a transparent conductive material.

According to some implementations of the present disclosure, the connection power line may be connected to a high-potential power line at one end and a high-potential power line at the other end to operate as a high-potential power line or may operate as a repair line connecting upper and lower points or left and right points of a point where disconnection occurs between the gate line and the plurality of vertical lines.

Although the present disclosure has been described above with reference to the exemplary drawings, the present disclosure is not limited by the implementations and drawings disclosed in the present disclosure, and it is apparent that various modifications can be made by those skilled in the art within the scope of the technical idea of the present disclosure. In addition, even when the operational effects according to the configuration of the present disclosure have not been explicitly described in the description of the implementations of the present disclosure, it is apparent that the effects predictable by the corresponding configuration should also be recognized.

What is claimed is:

1. A display apparatus comprising:
a plurality of sub-pixels adjacent to each other along a first direction;
a scan line disposed to extend in the first direction below the plurality of sub-pixels;
a plurality of data lines disposed to extend along a second direction between adjacent sub-pixels; and
repair circuits disposed at locations where the plurality of data lines and the scan line intersect.

2. The display apparatus of claim 1, wherein the repair circuits each include a first repair line for connecting two defective or disconnected portions of the scan line, and a second repair line for connecting two defective or disconnected portions of a data line.

3. The display apparatus of claim 2, wherein each of the first repair line and the second repair line includes a transparent conductive material.

4. The display apparatus of claim 3, wherein the transparent conductive material includes at least one of indium tin oxide (ITO), indium zinc oxide (IZO), or indium gallium zinc oxide (IGZO).

5. The display apparatus of claim 2, wherein the first repair line and the second repair line are disposed on a same layer.

6. The display apparatus of claim 2, wherein the first repair line and the second repair line are disposed on a different layer from the scan line or the data line.

7. The display apparatus of claim 2, wherein the first repair line and the second repair line are disposed on a same layer as an active layer of a sub-pixel.

8. The display apparatus of claim 2, wherein the first repair line and the second repair line are disposed not to overlap each other.

9. The display apparatus of claim 2, wherein the first repair line has a same material as the scan line.

10. The display apparatus of claim 2, wherein the second repair line has a same material as the data line.

11. The display apparatus of claim 2, wherein the first repair line and the second repair line are formed of one of molybdenum (Mo), aluminum (Al), chromium (Cr), gold (Au), titanium (Ti), nickel (Ni), neodymium (Nd), and copper (Cu), or an alloy of one or more of molybdenum (Mo), aluminum (Al), chromium (Cr), gold (Au), titanium (Ti), nickel (Ni), neodymium (Nd), or copper (Cu).

12. The display apparatus of claim 1, wherein the repair circuit includes:
a scan line on a substrate;
a buffer layer on the substrate and the scan line;
a repair line on the buffer layer;
a gate insulating layer on the buffer layer and the repair line; and
a passivation layer on the gate insulating layer.

13. The display apparatus of claim 1, wherein the repair circuit includes:
a repair line on a substrate;
a first buffer layer on the substrate and the repair line;
a data line on the first buffer layer;
a second buffer layer on the first buffer layer and the data line;
a gate insulating layer on the second buffer layer; and
a passivation layer on the gate insulating layer.

14. A display apparatus comprising:
a plurality of sub-pixels;
a gate line extending horizontally with respect to each sub-pixel;
a main power line disposed parallel to the gate line;
a plurality of vertical lines extending vertically with respect to each sub-pixel; and
an auxiliary power line disposed to extend horizontally to overlap at each location where the plurality of vertical lines intersect the gate line,
wherein the auxiliary power line has a spiral shape on each overlap portion.

15. The display apparatus of claim 14, wherein the plurality of vertical lines include power lines, data lines, and reference voltage lines.

16. The display apparatus of claim 14, wherein the auxiliary power line is formed of a transparent conductive material.

17. The display apparatus of claim 14, wherein the auxiliary power line is disposed above the main power line.

18. A display apparatus comprising:
a plurality of sub-pixels;
a gate line extending horizontally with respect to each sub-pixel;
a plurality of vertical lines extending vertically with respect to each sub-pixel; and
a connection power line disposed to extend horizontally to overlap at each location where the plurality of vertical lines intersect the gate line,
wherein the connection power line has a spiral shape on each of overlap portions.

19. The display apparatus of claim 18, wherein the connection power line is formed of a transparent conductive material.

20. The display apparatus of claim 19, wherein the connection power line is connected to a high-potential power line at one end and a high-potential power line at the other end to operate as a high-potential power line, or
operate as a repair line connecting upper point and lower points or left point and right points of a point where a disconnection occurs between the gate line and the plurality of vertical lines.
